(19) United States
(12) Patent Application Publication
(10) Pub. No.: US 2014/0326185 A1
(43) Pub. Date: Nov. 6, 2014

(54) INJECT AND EXHAUST DESIGN FOR EPI CHAMBER FLOW MANIPULATION

(71) Applicant: Applied Materials, Inc., Santa Clara, CA (US)

(72) Inventors: Shu-Kwan LAU, Sunnyvale, CA (US); Mehmet Tugrul SAMIR, Mountain View, CA (US)

(73) Assignee: APPLIED MATERIALS, INC., Santa Clara, CA (US)

(21) Appl. No.: 14/257,547

(22) Filed: Apr. 21, 2014

Related U.S. Application Data
(60) Provisional application No. 61/818,198, filed on May 1, 2013.

(51) Int. Cl. C23C 16/52; C23C 16/00

(52) U.S. Cl. CPC C23C 16/52; C23C 16/00
USPC 118/728

(57) ABSTRACT

The embodiments described herein generally relate to a flow control in a process chamber. The process chamber can include combinations of a flow control exhaust and a broad inject. The flow control exhaust and the broad inject can provide for controlled flow of process gases, as the gases both enter and leave the chamber, as well as controlling the gases already present in the chamber. Therefore, the overall deposition profile can be maintained more uniform.

### CROSS-REFERENCE TO RELATED APPLICATIONS

This application claims benefit of U.S. Provisional Patent Application Ser. No. 61/818,198 (APPM/20526L), filed May 1, 2013, which is herein incorporated by reference.

### BACKGROUND OF THE INVENTION

1. Field of the Invention

Embodiments disclosed herein generally relate to controlling flow in process chambers.

2. Description of the Related Art

An epitaxial layer is a crystalline film grown over a crystalline substrate. The underlying substrate acts as a template for the growing film, so that the crystallographic characteristics of the epitaxial layer are defined by the underlying crystalline substrate. That is, the crystalline substrate provides a crystallographic seed for the epitaxial growth. The substrate may be, for example, monocrystalline silicon, silicon germanium or an SOI wafer.

Growth of the epitaxial layer is commonly achieved using chemical vapor deposition (CVD) in an epitaxial deposition (Epi) chamber. The substrate is loaded into a CVD reactor, which is then purged with a non-reactive gas such as He, Ar, N₂ or H₂. The temperature of the reactor is ramped up, and a mixture of a carrier gas and a reactive gas is introduced into the reactor with specific flow dynamics. Dopant gases may also be introduced either during the deposition or implanted after deposition. When a desired thickness of the epitaxial layer has been achieved, non-reactive gases are again used to purge the reactor, and the temperature is ramped down.

Flow is a critical factor in epitaxial deposition (Epi) chamber design and Epi deposition performance. Epi chambers generally focus on creating a uniform flow field. As Epi chamber processes become more complicated, larger wafers are expected to be used and uniformity of the flow fields will become more difficult.

Thus, there is a need in the art for differential flow control during substrate processing to achieve epitaxial growth.

### SUMMARY OF THE INVENTION

The embodiments described herein generally relate to processing chambers with structures to provide for gas flow control. In one embodiment, a device can include a process chamber, a substrate support disposed within the process chamber for supporting a substrate, the substrate support generally defining a processing region of the process chamber, and a broad inject in fluid connection with the processing region. The broad inject can include one or more inject entrances, one or more inject paths in fluid connection with at least one of the one or more inject entrances and one or more injection ports in fluid connection with at least one of the inject paths.

In another embodiment, a device can include a process chamber, a substrate support disposed within the process chamber for supporting a substrate, a lower dome disposed below the substrate support, an upper dome disposed opposing the lower dome, a base ring disposed between the upper dome and the lower dome, the upper dome, the base ring and the lower dome generally defining a processing region of the process chamber and a flow control exhaust in fluid connection with the processing region, the flow control exhaust comprising one or more flow control structures.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic sectional view of a backside heating process chamber 100 according to one embodiment;

FIGS. 2A-2G depict a flow control gas outlet according to one embodiment;

FIG. 3A depicts a top cross sectional view of a process chamber with broad inject according to one embodiment; and

FIG. 3B depicts a zonal flow as received by a process chamber from a broad inject, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments disclosed herein generally relate to inlets and outlets for use with a process chamber to control the flow field in the process chamber. Described herein is a flow control gas outlet and a broad inject for use with one or more process chambers. Control of the flow field is expected to become more important as device sizes diminish. By controlling the flow rate, the flow velocity and the directionality of the gases as they both enter and exit the processing area, the dynamics of the gases used in deposition, and thus the deposition of the thin film on the substrate, can be better controlled. The embodiments of the inventions disclosed herein are more clearly described with reference to the figures below

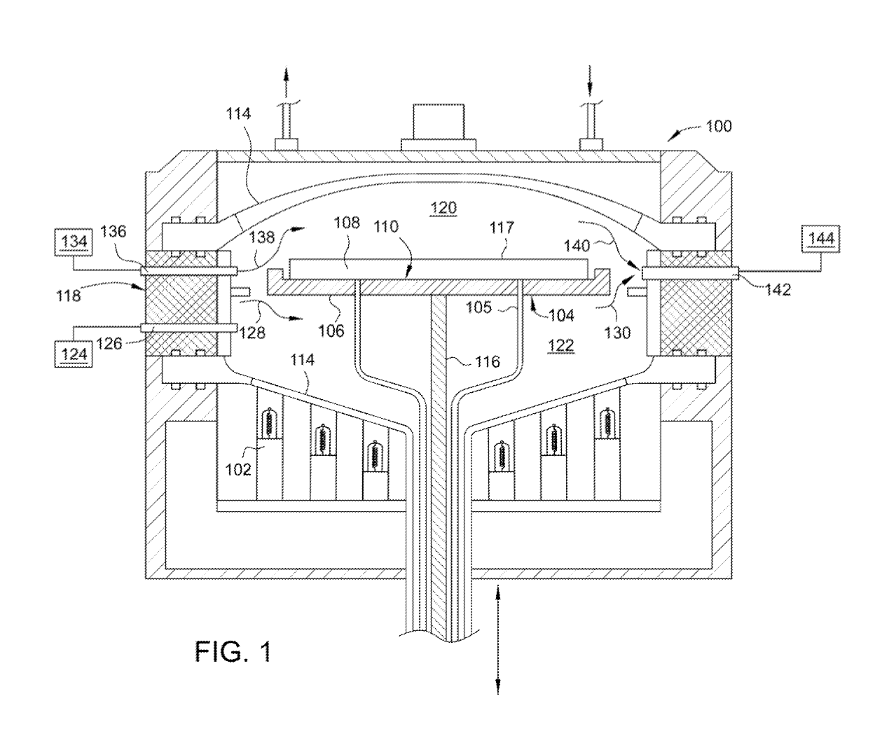

FIG. 1 illustrates a schematic sectional view of a backside heating process chamber 100 according to one embodiment. One example of the process chamber that may be adapted to benefit from the invention is an Epi process chamber, which is available from Applied Materials, Inc., located in Santa Clara, Calif. It is contemplated that other processing chambers, including those from other manufacturers, may be adapted to practice the present inventions.

The process chamber 100 may be used to process one or more substrates, including the deposition of a material on an upper surface of a substrate 108. The process chamber 100 can include a process chamber heating device, such as an array of radiant heating lamps 102 for heating, among other components, a back side 104 of a substrate support 106 or the back side of the substrate 108 disposed within the process chamber 100. The substrate support 106 may be a disk-like substrate support 106 as shown, or may be a ring-like substrate support (not shown), which supports the substrate from the edge of the substrate or may be a pin-type support which supports the substrate from the bottom by minimal contact posts or pins.

In this embodiment, the substrate support 106 is depicted as located within the process chamber 100 between an upper dome 114 and a lower dome 112. The upper dome 114 and the lower dome 112, along with a base ring 118 that is disposed between the upper dome 114 and lower dome 112, can define an internal region of the process chamber 100. The substrate 108 (not to scale) can be brought into the process chamber 100 and positioned onto the substrate support 106 through a loading port (not shown), which is obscured by the substrate support 106.

The base ring 118 can generally include the loading port, a process gas inlet 136, and a gas outlet 142. The base ring 118 may have a generally oblong shape with the long side on the loading port and the short sides on the process gas inlet 136 and the gas outlet 142, respectively. The base ring 118 may have any desired shape as long as the loading port 103, the process gas inlet 136 and the gas outlet 142 are angularly offset at about 90° with respect to each other and the loading port. For example, the loading port 103 may be located at a side between the process gas inlet 136 and the gas outlet 142, with the process gas inlet 136 and the gas outlet 142 disposed at opposing ends of the base ring 118. In various embodiments, the loading port, the process gas inlet 136 and the gas outlet 142 are aligned to each other and disposed at substantially the same level.

The substrate support 106 is shown in an elevated processing position, but may be vertically traversed by an actuator (not shown) to a loading position below the processing position to allow lift pins 105 to contact the lower dome 112, passing through holes in the substrate support 106 and a central shaft 116, and raise the substrate 108 from the substrate support 106. A robot (not shown) may then enter the process chamber 100 to engage and remove the substrate 108 therefrom though the loading port. The substrate support 106 then may be actuated up to the processing position to place the substrate 108, with its device side 117 facing up, on a front side 110 of the substrate support 106.

The substrate support 106, while located in the processing position, divides the internal volume of the process chamber 100 into a process gas region 120 that is above the substrate, and a purge gas region 122 below the substrate support 106. The substrate support 106 can be rotated during processing by the central shaft 116 to minimize the effect of thermal and process gas flow spatial anomalies within the process chamber 100 and thus facilitate uniform processing of the substrate 108. The substrate support 106 is supported by the central shaft 116, which moves the substrate 108 in an up and down direction 134 during loading and unloading, and in some instances, processing of the substrate 108. The substrate support 106 may be formed from silicon carbide or graphite coated with silicon carbide to absorb radiant energy from the lamps 102 and conduct the radiant energy to the substrate 108.

In general, the central window portion of the upper dome 114 and the bottom of the lower dome 112 are formed from an optically transparent material such as quartz. The thickness and the degree of curvature of the upper dome 114 may be configured to manipulate the uniformity of the flow field in the process chamber.

The lamps 102 can be disposed adjacent to and beneath the lower dome 112 in a specified manner around the central shaft 116 to independently control the temperature at various regions of the substrate 108 as the process gas passes over, thereby facilitating the deposition of a material onto the upper surface of the substrate 108. The lamps 102 may configured to heat the substrate 108 to a temperature within a range of about 200 degrees Celsius to about 1600 degrees Celsius. While not discussed here in detail, the deposited material may include silicon, doped silicon, germanium, doped germanium, silicon germanium, doped silicon germanium, gallium arsenide, gallium nitride, or aluminum gallium nitride.

Process gas supplied from a process gas supply source 134 is introduced into the process gas region 120 through a process gas inlet 136 formed in the sidewall of the base ring 118. The process gas inlet 136 is configured to direct the process gas in a direction which can be generally radially inward. During the film formation process, the substrate support 106 is located in the processing position, which can be adjacent to and at about the same elevation as the process gas inlet 136, allowing the process gas to flow up and round along flow path 138 across the upper surface of the substrate 108. The process gas exits the process gas region 120 (along flow path 140) through a gas outlet 142 located on the opposite side of the process chamber 100 as the process gas inlet 136. Removal of the process gas through the gas outlet 142 may be facilitated by a vacuum pump 144 coupled thereto.

Purge gas supplied from a purge gas source 124 is introduced to the purge gas region 122 through a purge gas inlet 126 formed in the sidewall of the base ring 118. The purge gas inlet 126 is disposed at an elevation below the process gas inlet 136. If the circular shield 167 is used, the circular shield 167 may be disposed between the process gas inlet 136 and the purge gas inlet 126. In either case, the purge gas inlet 126 is configured to direct the purge gas in a generally radially inward direction. If desired, the purge gas inlet 126 may be configured to direct the purge gas in an upward direction. During the film formation process, the substrate support 106 is located at a position such that the purge gas flows down and round along flow path 128 across back side 104 of the substrate support 106. Without being bound by any particular theory, the flowing of the purge gas is believed to prevent or substantially avoid the flow of the process gas from entering into the purge gas region 122, or to reduce diffusion of the process gas entering the purge gas region 122 (i.e., the region under the substrate support 106). The purge gas exits the purge gas region 122 (along flow path 130) and is exhausted out of the process chamber through the gas outlet 142 located on the opposite side of the process chamber 100 as the purge gas inlet 126.

### Flow Control Exhaust

Though uniform flow is commonly believed to be preferential, more advanced deposition processes may require higher order control of the flow field. Thus, a flow control exhaust can provide higher order control of one or more zones of the flow field. The flow control exhaust can have bias conductance, which can result in flow zonality across the exhaust. Flow zonality can propagate some distance upstream, where the deposition on the wafer can be affected. Flow control exhaust can be incorporated with other flow control mechanisms, such as zonal inject, to achieve a bias flow field across the processing region, such as the process gas region 120 described with reference to FIG. 1. Flow control exhaust can be achieved through an apparatus, such as a flow control gas outlet.

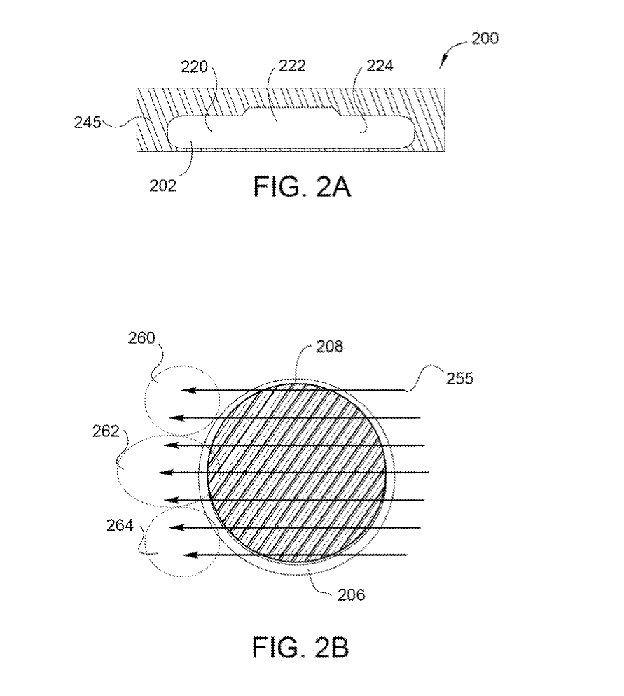

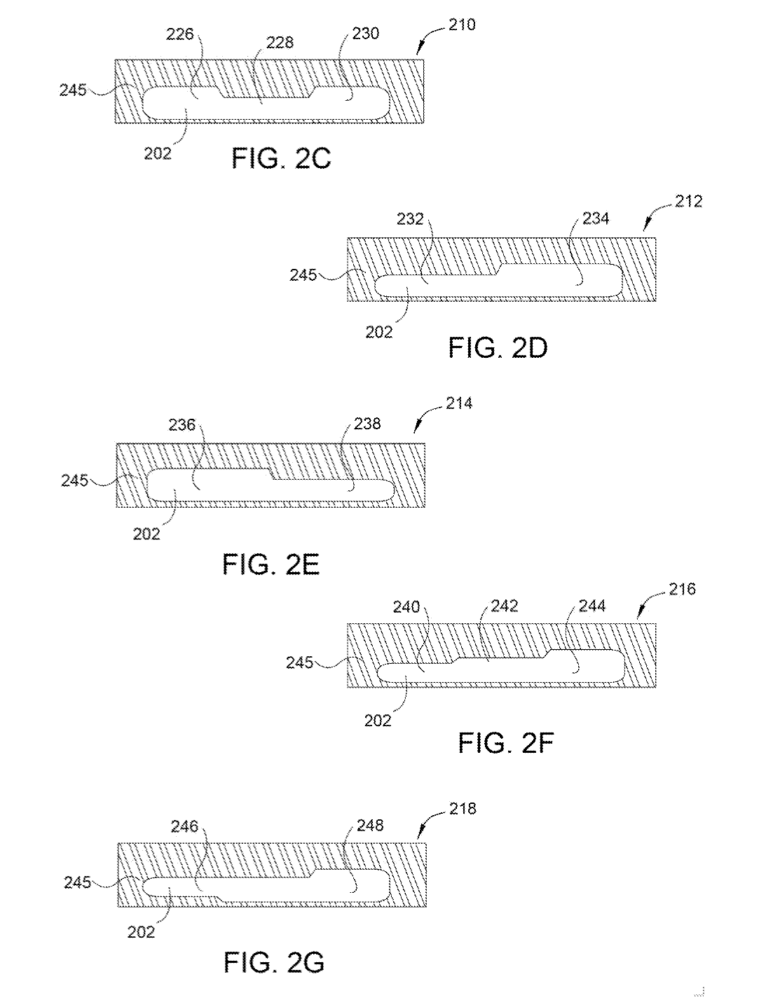

FIGS. 2A-2G depict a flow control gas outlet 200 according to one embodiment. In one embodiment, the gas outlet 142 described with reference to FIG. 1 can be the flow control gas outlet 200. The flow control gas outlet can have an aperture 202 formed in the gas outlet body 245. In some embodiments, the flow control gas outlet 200 can have an aperture 202 with a variety of formations, such that gases entering the gas outlet 242 can have a different velocity as determined by position with respect to the opening.

FIG. 2A is a flow control gas outlet 200 according to one embodiment. Though the aperture 202 is depicted here as being entirely surrounded by the gas outlet body 245, the aperture 202 can be formed as an opening in a combination of components. For example, the aperture 202 can be an opening formed between the chamber wall (not shown) and the gas outlet body 245. Further configurations are contemplated without being directly described herein.

In this embodiment, the aperture 202 has plurality of flow control structures formed therein, depicted herein as a first structure 220, a second structure 222 and a third structure 224. In one or more embodiments, the flow control structures can be more or fewer than three. The first structure 220, the second structure 222 and the third structure 224 can each have a variety of shapes such that both the angle of entry and the space for entry can be used to control directionality and velocity of present gases 255 as they exit the chamber. Present gases can include process gases, the purge gas or other gases which can be present during processing. The shapes used for each of the first structure 220, the second structure 222 and the third structure 224 (or further structures when more or less than three structures are used) can be different from one another such each structure creates a definable zone in the present gas 255.

In this embodiment, the first structure 220 and the third structure 224 are smaller than the second structure 222. Thus, it is expected that gases which are proximate to the second structure 222 can flow at a higher volume and a lower velocity when the vacuum pump 144 is in operation with comparison to gases which are proximate to the first structure 220 or the third structure 224.

FIG. 2B is an overhead view of the present gas 255 as expected with relation to the flow control gas outlet 200 described in FIG. 2A. The present gas 255 can be delivered from the gas inlet 136 as described with reference to FIG. 1. The present gas 255 flows over the substrate 208 which is located on the substrate support 206 with a specific flow rate and a specific flow velocity. The present gas 255 is then received by the flow control gas outlet 200. Based on the shapes of the first structure 220, the second structure 222 and the third structure 224, the flow rate and the flow velocity of the present gas 255 is altered in proximity to the structures. Thus, the first structure 220, the second structure 222 and the third structure 224 creates a first zone 260, a second zone 262 and the third zone 264. Assuming that on other structure have altered the flow of the present gas 255 at a specific zone, the second zone 262 is expected to flow slower than the first zone 260 and the third zone 264.

FIG. 2C depicts a flow control gas outlet 210, according to another embodiment. In this embodiment, the aperture 202 has three flow control structures formed in a gas outlet body 245, depicted herein as a first structure 226, a second structure 228 and a third structure 230. The first structure 226 and the third structure 230 are larger than the second structure 228. Thus, it is expected that gases which are proximate to the second structure 228 can flow at a lower volume and a higher velocity when the vacuum pump 144 is in operation with comparison to gases which are proximate to the first structure 226 or the third structure 230. Thus, in this embodiment, the present gas 255 will flow faster in the center than at the edges, as the process gas 255 approaches the flow control gas outlet.

FIG. 2D depicts a flow control gas outlet 212, according to another embodiment. In this embodiment, the aperture 202 has two flow control structures formed in a gas outlet body 245, depicted herein as a first structure 232 and a second structure 234. The third structure shown in the previous embodiments has been omitted which increases the size of the zones created in the present gas 255 while reducing the number of total definable zones. The first structure 232 is smaller than the second structure 234. Thus, it is expected that gases which are proximate to the second structure 234 can flow at a higher volume and a lower velocity when the vacuum pump 144 is in operation with comparison to gases which are proximate to the first structure 232. Thus, in this embodiment, the present gas 255 will flow faster at the first edge than at the second edge.

FIG. 2E depicts a flow control gas outlet 214, according to another embodiment. In this embodiment, the aperture 202 has two flow control structures formed in a gas outlet body 245, depicted herein as a first structure 236 and a second structure 238. The third structure shown in the previous embodiments has been omitted which increases the size of the zones created in the present gas 255 while reducing the number of total definable zones. The first structure 236 is larger than the second structure 238. Thus, it is expected that gases which are proximate to the second structure 238 can flow at a lower volume and a higher velocity when the vacuum pump 144 is in operation with comparison to gases which are proximate to the first structure 236. Thus, in this embodiment, the present gas 255 will flow faster at the second edge than at the first edge.

FIG. 2F depicts a flow control gas outlet 216, according to another embodiment. In this embodiment, the aperture 202 has three flow control structures formed in a gas outlet body 245, depicted herein as a first structure 240, a second structure 242 and a third structure 244. Shown here, the first structure 240 is smaller than the second structure 242 which is smaller than the third structure 244. Thus, it is expected that present gas 255 will flow at the lowest volume and the highest velocity near the third structure 244. Further, the volume of flow will increase while the speed of flow will decrease progressively from the third zone 264 to the first zone 260, described with reference to FIG. 2B.

FIG. 2G depicts a flow control gas outlet 218, according to another embodiment. In this embodiment, the aperture 202 has three flow control structures formed in a gas outlet body 245, depicted herein as a first structure 246, a second structure 252 and a third structure 248. Shown here, the first structure 246 is smaller than the second structure 252 which is smaller than the third structure 248. Further shown is a change in spacing on the first structure 246 between the bottom edge of the gas outlet body 245 and the bottom edge of the aperture 202. Thus, it is expected that present gas 255 will flow at the lowest volume and the highest velocity near the third structure 248. Further, the volume of flow will increase while the speed of flow will decrease progressively from the third zone 264 to the first zone 260, described with reference to FIG. 2B.

In one or more of the embodiments described above, the flow control gas outlet 218 can be a flow control insert. The flow control inserts can have one or more flow control structures, as shown with reference to FIGS. 2A-2G. The flow control inserts can be composed of a material resistant to the chemistry and temperatures of the processing chamber. In one embodiment, the flow control insert is made of quartz. In operation, flow control exhaust can include a positioned flow control insert selected from a plurality of flow control inserts. The positioned flow control insert can be exchanged with one of the plurality of flow control inserts to change one or more flow parameters of the flow control exhaust. The exchange can be done manually, such as in between operating cycles or the exchange can be part of an automated system.

Without intending to be bound by theory, it is believed that designs which act only to control flow at the gas inlet lack flow control as the gases approach the gas outlet. In standard chambers, the process gas can enter from one side of the chamber and flow over the substrate. Various structures and designs can be incorporated to assure that the flow remains uniform. However, the uniformity of this flow, as the present gas comes in contact with various obstacles, diminished over time. By incorporating a flow control gas outlet, such as described with reference to the figures above, the gas flow at all points of the chamber can be controlled.

### Broad Inject

Zonal control of the flow field can be further manipulated upstream using a broad inject design. Current Epi inject gas enters the chamber from the openings in the lower liner. The openings of these designs can have total width a little more than wafer diameter and the openings can span from +45 degrees to −45 degrees from the centerline. Embodiments employing the broad inject deliver gas through the upper liner from a larger span. The positioning of the holes for the broad inject can be from +90 degrees to −90 degrees from the centerline (180 degrees of circumference). The inject entrance can be in the form of slots or holes. The injection ports can also be angled with respect to the wafer, such that the gases are delivered to the substrate at an angle. As such, the broad inject design can create a more controlled zonal flow. In addition, each injection port will have a shorter path to the wafer, making localized uniformity control more effective. The larger span of inject angle will also create a larger reaction zone, which can reduce the deposition non-uniformity due to rotation and process cycle.

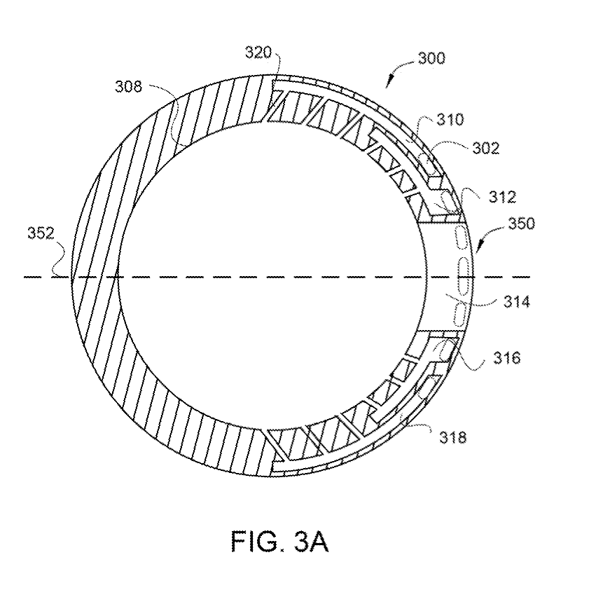

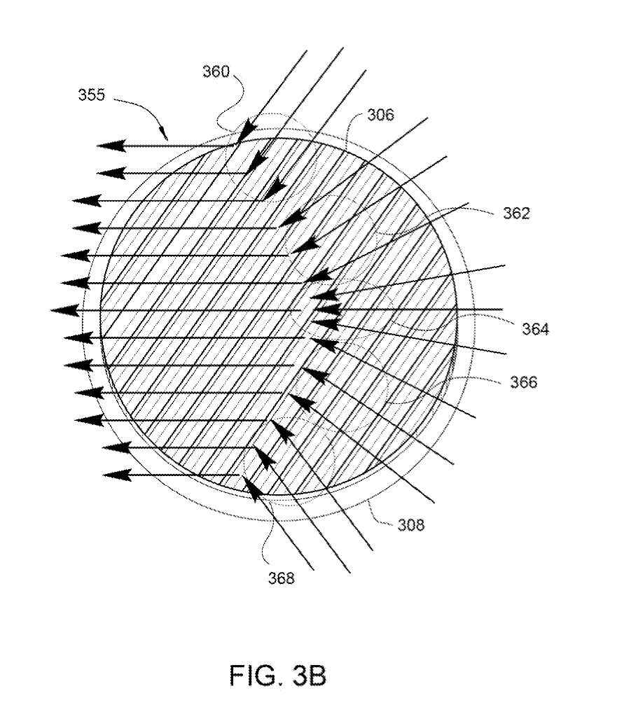

FIG. 3A depicts a top cross sectional view of a process chamber 300 with broad inject according to one embodiment. The process chamber 300 is depicted with the substrate support 308 in fluid connection with a broad inject 350. The broad inject 350 can have one or more injection paths, depicted here as a broad inject 350 with a first path 310, a second path 312, a third path 314, a fourth path 316 and a fifth path 318. Each of the injection paths can have at least one inject entrance 302, such as seven inject entrances 302. More or fewer inject entrances can be used without diverging from the embodiments described herein, so long as all of the injection paths is in fluid connection with at least one inject entrance 302.

The inject paths can be positioned can be positioned between −90 degrees and +90 degrees from a centerline 352. The first path 312 is depicted as being a linear path between −90 degrees and −25 degrees from the centerline 352. The second path 314 is depicted as being a linear path between −50 degrees and −10 degrees from the centerline 352. The third path 314 is depicted as being bisected by the centerline 352, with the area of the third path being between −10 degrees and +10 degrees. The fourth path 316 is depicted as being a linear path between +10 degrees and +50 degrees from the centerline 352. The fifth path 318 is depicted as being a linear path between +25 degrees and +90 degrees from the centerline 352. Each of the inject paths may be of a different size and shape than depicted. Further, the depiction of the positioning and orientation of the inject paths may be altered, such that the design described here can be incorporated with other inject designs. In one embodiment, the broad inject design is incorporated with an inject which is perpendicular to the centerline 352.

Each of the injection paths may be connected with one or more inject ports 320. The inject ports 320 can inject gas into the process area with both a separate directionality and velocity from other inject ports 320. The inject ports 320, though depicted here as being of approximately the same size and shape, this is not intended to be limiting of possible embodiments. Each of the inject ports 320 can inject gas into the process area at an independent velocity, flow rate and directionality with comparison to the other inject ports 320. More or fewer inject paths or inject ports 320 can be used without diverging from the embodiments described herein.

In operation, the process gas can flow through the inject entrances 302 at a first velocity, flow rate, and directionality. The process gas can then move into an inject path, such as the first path 310, the second path 312, the third path 314, the fourth path 316 and the fifth path 318, which will redirect the process gas toward the inject ports 320. The inject ports 320 can then deliver the gas to the process area at a second velocity, flow rate and directionality based on the size, shape and angle of the inject port 320.

The process gas can be directed by the inject ports 320 toward one or more regions in the processing chamber. In the embodiment shown here, the inject ports 320 direct the process gas toward a focus point in the chamber. The focus point can be a specific region in the process chamber, a specific part of the process chamber, or toward a point outside of the process chamber. Further, the inject ports 320 can direct the process gas toward multiple focus points. Using the example shown here with twelve (12) exhaust ports 320, the first through third exhaust ports 320 can direct the process gas at a first focus point, the fourth through sixth exhaust ports 320 can direct the process gas at a second focus point, the seventh through ninth exhaust ports 320 can direct the process gas at a third focus point, and the tenth through twelfth exhaust ports 320 can direct the process gas at a fourth focus point. In one embodiment, the focus point is the exhaust port of the processing chamber, such as the flow control exhaust 200.

FIG. 3B depicts a zonal flow as received by a process chamber from a broad inject, according to one embodiment. Depicted here is the substrate support 308 with a substrate 306 disposed thereon. It is understood that certain components, including necessary components, are not depicted here for clarity. The inject ports 320 each deliver process gas to the process area, creating a flow field 355. The flow field 355 is a combination of the gases delivered, the velocity and the flow rate the delivered gas is received at in the process chamber and components in the chamber which might affect one or more of the properties of the delivered gas.

The angles of the delivered gas received from the inject ports creates one or more zones in the flow field 355, depicted here as a first zone 360, a second zone 362, a third zone 364, a fourth zone 366 and a fifth zone 368. Each of these zones may have a different velocity, flow rate, or directionality than the other zones.

Without intending to be bound by theory, it is believed that independent control of the gas delivery based on position on the substrate 308 can help create a more uniform deposition profile. Prior inject designs only allowed for limited tuning due in part to the distance of the substrate from the inject port or ports and the characteristics of the inject port itself. The broad inject design can create controlled areas of non-uniformity in the flow field. The positioning, flow rate and velocity of the injection ports along the flow path can be used to energize and direct the flow. Thus, the broad inject design can maintain higher uniformity along the substrate from inject to exhaust.

In one embodiment, a process chamber can include a chamber body; a substrate support disposed within the chamber body for supporting a substrate, the substrate support generally defining a processing region of the process chamber; and a broad inject in fluid connection with the processing region. the broad inject having a ring shape. Further, the broad inject can have a centerline; a plurality of inject entrances; a plurality of inject paths in fluid connection with at least one of the plurality of inject entrances; and a plurality of inject ports in fluid connection with at least one of the inject paths.

The process chamber can further include at least one of the inject ports forming an angle with the centerline.

The process chamber can further include the plurality of inject ports being oriented at an angle with respect to the centerline, wherein each inject port directs gas flow at a focus point in the processing chamber.

The process chamber can further include at least one of the inject ports directing gas flow toward an exhaust port of the process chamber.

The process chamber can further include each of the inject paths being independently connected to at least one of the one or more inject entrances.

The process chamber can further include a flow control exhaust in fluid connection with the processing region, the flow control exhaust comprising one or more flow control structures.

The process chamber can further include the flow control exhaust comprising a replaceable flow control insert with a varying cross-section that defines one or more flow parameters of the flow control exhaust.

The process chamber can further include the flow control exhaust having a varying cross-section that defines at least two flow zones to create flow uniformity in a process chamber.

The process chamber can further include the flow zones reducing gas flow non-uniformities in the process chamber.

The process chamber can further include the flow control exhaust having three flow control structures.

The process chamber can further include the flow control exhaust creating at least two zones defined by difference in velocity of the process gas.

The process chamber can further include the flow control structures being symmetrical about a centerline of the process chamber.

In another embodiment, a process chamber can include a chamber body; a substrate support disposed within the chamber body for supporting a substrate; a lower dome disposed below the substrate support; an upper dome disposed opposing the lower dome; a base ring disposed between the upper dome and the lower dome, the upper dome, the base ring and the lower dome generally defining a processing region of the process chamber; and a flow control exhaust in fluid connection with the processing region, the flow control exhaust comprising one or more flow control structures.

The process chamber can further include the flow control exhaust having three flow control structures.

The process chamber can further include the flow control exhaust having at least two zones defined by difference in velocity of the process gas.

The process chamber can further include the flow control exhaust comprising a removable flow control insert that has the flow control structures, wherein the flow control insert has at least two flow zones with different gas flow parameters.

The process chamber can further include the flow control insert having a varying cross-section that creates at least two flow zones to create flow uniformity in a process chamber.

The process chamber can further include the flow zones reducing gas flow non-uniformities in the process chamber.

The process chamber can further include the flow control structures being symmetrical about a centerline of the process chamber.

In another embodiment, a process chamber can include a chamber body; a substrate support disposed within the chamber body for supporting a substrate, the substrate support generally defining a processing region within the chamber body; and a broad inject in fluid connection with the processing region, the broad inject having a ring shape. The broad inject can include a plurality of inject entrances; a plurality of inject paths in fluid connection with at least one of the one or more inject entrances; and a plurality of inject ports in fluid connection with at least one of the inject paths, wherein the plurality of inject ports are oriented at an angle not parallel with respect to a centerline of the chamber body; and a flow control exhaust in fluid connection with the processing region, the flow control exhaust comprising a plurality of flow control structures, wherein the plurality of flow control structures define at least two flow zones to impart different flow parameters to a process gas, and wherein at least one inject port directs gas flow toward the flow control exhaust.

While the foregoing is directed to embodiments of the invention, other and further embodiments of the invention may be devised without departing from the basic scope thereof.

1. A process chamber, comprising:
a chamber body;
a substrate support disposed within the chamber body for supporting a substrate, the substrate support generally defining a processing region of the process chamber; and
a broad inject in fluid connection with the processing region, the broad inject having a ring shape and comprising:
a centerline;
a plurality of inject entrances;
a plurality of inject paths in fluid connection with at least one of the plurality of inject entrances; and
a plurality of inject ports in fluid connection with at least one of the inject paths.

2. The process chamber of claim 1, wherein at least one of the inject ports forms an angle with the centerline.

3. The process chamber of claim 1, wherein the plurality of inject ports are oriented at an angle with respect to the centerline, wherein each inject port directs gas flow at a focus point in the processing chamber.

4. The process chamber of claim 1, wherein at least one of the inject ports directs gas flow toward an exhaust port of the process chamber.

5. The process chamber of claim 4, wherein each of the inject paths is independently connected to at least one of the one or more inject entrances.

6. The process chamber of claim 1, further comprising a flow control exhaust in fluid connection with the processing region, the flow control exhaust comprising one or more flow control structures.

7. The process chamber of claim 6, wherein the flow control exhaust comprises a replaceable flow control insert with a varying cross-section that defines one or more flow parameters of the flow control exhaust.

8. The process chamber of claim 6, wherein the flow control exhaust has a varying cross-section that defines at least two flow zones to create flow uniformity in a process chamber.

9. The process chamber of claim 8, wherein the flow zones reduce gas flow non-uniformities in the process chamber.

10. The process chamber of claim 6, wherein the flow control exhaust has three flow control structures.

11. The process chamber of claim 6, wherein the flow control exhaust creates at least two zones defined by difference in velocity of the process gas.

12. The process chamber of claim 6, wherein the flow control structures are symmetrical about a centerline of the process chamber.

13. A process chamber, comprising:
a chamber body;
a substrate support disposed within the chamber body for supporting a substrate;
a lower dome disposed below the substrate support;
an upper dome disposed opposing the lower dome;
a base ring disposed between the upper dome and the lower dome, the upper dome, the base ring and the lower dome generally defining a processing region of the process chamber; and
a flow control exhaust in fluid connection with the processing region, the flow control exhaust comprising one or more flow control structures.

14. The process chamber of claim 13, wherein the flow control exhaust has three flow control structures.

15. The process chamber of claim 13, wherein the flow control exhaust has at least two zones defined by difference in velocity of the process gas.

16. The process chamber of claim 13, wherein the flow control exhaust comprises a removable flow control insert that has the flow control structures, wherein the flow control insert has at least two flow zones with different gas flow parameters.

17. The process chamber of claim 16, wherein the flow control insert has a varying cross-section that creates the at least two flow zones to create flow uniformity in a process chamber.

18. The process chamber of claim 17, wherein the flow zones reduce gas flow non-uniformities in the process chamber.

19. The process chamber of claim 13, wherein the flow control structures are symmetrical about a centerline of the process chamber.

20. A process chamber, comprising:
a chamber body;
a substrate support disposed within the chamber body for supporting a substrate, the substrate support generally defining a processing region within the chamber body;
a broad inject in fluid connection with the processing region, the broad inject having a ring shape and comprising:
a plurality of inject entrances;
a plurality of inject paths in fluid connection with at least one of the one or more inject entrances; and
a plurality of inject ports in fluid connection with at least one of the inject paths, wherein the plurality of inject ports are oriented at an angle not parallel with respect to a centerline of the chamber body; and
a flow control exhaust in fluid connection with the processing region, the flow control exhaust comprising a plurality of flow control structures, wherein the plurality of flow control structures define at least two flow zones to impart different flow parameters to a process gas, and wherein at least one inject port directs gas flow toward the flow control exhaust.
